(19) United States
(12) Patent Application Publication
(10) Pub. No.: US 2024/0168505 A1
(43) Pub. Date: May 23, 2024

(54) VOLTAGE CONTROL DEVICE USING MEASURED EQUIPMENT LOAD VOLTAGE

(71) Applicant: CROCUS INC., Seoul (KR)

(72) Inventors: Bok Nyun KIM, Seoul (KR); DANIEL JESUPH LIM, Seoul (KR)

(21) Appl. No.: 18/237,944

(22) Filed: Aug. 25, 2023

(30) Foreign Application Priority Data
Nov. 18, 2022 (KR) 10-2022-0155631

(51) Int. Cl. G05F 1/10; G01R 19/00

(52) U.S. Cl. CPC G05F 1/10; G01R 19/0084

(57) ABSTRACT

A voltage control device includes a data collector, a statistics processor, a voltage predictor, a voltage calculator, and a controller. The data collector collects voltage data from a plurality of equipment loads. The statistics processor statistically processes the voltage data collected by the data collector according to a prediction period. The voltage predictor predicts a future voltage distribution using statistical values from the statistics processor. The voltage calculator calculates a voltage to be controlled using the future voltage distribution predicted by the voltage predictor. The controller generates an instruction to perform control at the voltage calculated by the voltage calculator.

### CROSS REFERENCE TO RELATED APPLICATION AND CLAIM OF PRIORITY

This application claims the benefit under 35 USC § 119 of Korean Patent Application No. 10-2022-0155631 filed on Nov. 18, 2022, in the Korean Intellectual Property Office (KIPO), the entire disclosure of which is incorporated herein by reference for all purposes.

### BACKGROUND

### 1. Field of the Invention

The present disclosure relates to a voltage control device configured to calculate an optimal operating voltage directly using a voltage actually measured from an equipment load instead of from a bus line of a substation.

### 2. Description of the Related Art

Voltage control devices of the related art generally control a voltage on the basis of a bus voltage, for example, by calculating the amount of a change in a bus voltage using flow calculation.

For example, an on-load tap changer (OLTC) may automatically control a voltage by means of an automatic voltage regulator (AVR) regulating a voltage on the second side of a substation by changing the tap location of a transformer. At this time, the line drop compensation (LDC) method may generally be used.

In a case in which the bus line of the substation or a place adjacent to the bus line is used as a measurement reference, generally, in optimized voltage control of a power system as in the LDC method of the AVR, a voltage drop from the bus line to each branched equipment load is calculated and, in general, voltage regulators are controlled on the basis of the calculated voltage drop.

In a number of cases, the determined voltage drop from the bus line to the load center of the equipment may differ from an actual voltage drop on a distribution line. In particular, when a plurality of distributed loads are connected, an error on the equipment may be further increased.

The foregoing is intended merely to aid in the understanding of the background of the present disclosure, and is not intended to mean that the present disclosure falls within the purview of the related art that is already known to those skilled in the art.

### SUMMARY

A voltage control device according to the present disclosure is intended to overcome the problem related to voltage control using flow calculation or the like on the basis of a bus line, and may perform optimal voltage control using voltage data obtained in real time from respective equipment loads branched from the bus line.

In order to achieve the above objective, according to one aspect of the present disclosure, there is provided a voltage control device including: a data collector collecting voltage data from a plurality of equipment loads; a statistics processor statistically processing the voltage data collected by the data collector according to a prediction period; a voltage predictor predicting a future voltage distribution using statistical values from the statistics processor; a voltage calculator calculating a voltage to be controlled using the future voltage distribution predicted by the voltage predictor; and a controller generating an instruction to perform control at the voltage calculated by the voltage calculator.

In conventional flow calculation, a voltage control process based on a bus line uses the bus line as a reference in most cases, and modeling for simplifying a complicated power system is required. In this simplification process, the difference from the distribution of complicatedly-branched actual equipment loads may be increased.

Accordingly, the present disclosure may predict an optimal control voltage by directly using and analyzing voltage data obtained in real time from respective equipment loads branched from the bus line in order to minimize an error caused by conventional simplification of modeling.

In addition, the present disclosure may calculate an optimal voltage by regarding the entirety of the equipment loads as a single group, instead of calculating an optimal voltage of each of the equipment loads.

In addition, an intended level of confidence may be set for optimal voltage distribution from actually measured voltage data of predicted equipment loads. The present disclosure may control the equipment loads at the optimal voltage meeting the confidence set from a predicted future voltage distribution.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a conceptual diagram illustrating equipment loads to be controlled by a voltage control device according to the present disclosure;

FIGS. 2A to 2C are graphs sequentially illustrating a prediction process of a future voltage distribution performed by a voltage predictor according to the present disclosure;

FIG. 3 is a graph illustrating the future voltage distribution according to the present disclosure;

FIG. 4 is a graph illustrating a confidence interval and voltage control according to the present disclosure; and

FIG. 5 is a graph illustrating an embodiment of FIG. 4.

### DETAILED DESCRIPTION OF THE DISCLOSURE

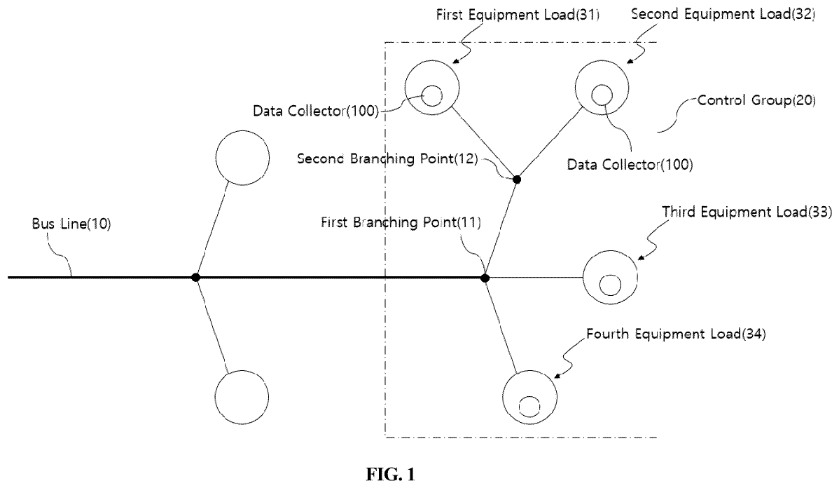

Hereinafter, a voltage control device according to the present disclosure will be described with reference to FIGS. 1 to 5.

Conventional voltage control to be compared may be realized by calculating an optimal controlled voltage by modeling in which flow calculation or the like is performed on the basis of a bus line 10. In this process, the distribution of branched loads of a complicated power system may be simplified. When equipment loads are branched into complicated systems, an optimal voltage obtained on the basis of the bus line 10 may not be optimal for equipment loads 30 at ends.

Thus, the voltage control device according to the present disclosure may measure in real time power data including the voltage of equipment loads 30, i.e., ends of the power system, collect the power data measured in real time, and calculate predicted future power data directly using the measured and collected power data.

Hereinafter, the measured power data and the predicted power data will be regarded as voltages in the following description, and the concept of the process of calculating an optimal voltage according to the present disclosure may be expanded to be used in analyzing other parameters related to electricity.

The equipment loads 30 may be branched to a variety of layers from the bus line 10 of the power system and be subjected to the optimal voltage calculation by the voltage control device according to the present disclosure.

Among the equipment loads 30 branched from the bus line 10, some equipment loads 30 subjected to the voltage control according to the present disclosure may belong to a control group 20.

The voltage control device may be used by an entity that manages the bus line as well as a substation of the power system or by an entity separated from the bus line management entity to distribute or manage actually-branched power to the equipment loads.

Referring to FIG. 1, an embodiment of the control group 20 is illustrated. Both a first equipment load 31 and a second equipment load 32 are branched as a single branch from the bus line 10 at a first branching point 11. A third equipment load 33 may be branched as a separate branch from the first equipment load 31 and the second equipment load 32. Afterwards, the first equipment load 31 and the second equipment load 32 may be secondarily divided into separate branches at a second branching point 12. In this manner, a plurality of branching points and branched layers may be formed at ends of the power system.

In this case, according to the conventional flow calculation to be compared, a process of predicting a voltage drop or the like of each of the equipment loads through the respective branching points in order to calculate an optimal voltage on the basis of the bus line 10 and then reversely calculating the voltage of the bus line 10 on the basis of the predicted voltage of the equipment loads or the voltage of an equipment load intended to be set may be necessary.

When the equipment loads are branched two times, both the first branching and the second branching should be reflected on the optimal voltage calculation process. In the same manner, in the equipment loads branched n times, all of n number of branches should be considered, thereby causing the calculation to be significantly difficult. Even in the case that modeling of respective branch nodes is simplified, it is difficult to guarantee that a solution of an optimal voltage calculation equation will be clearly obtained. As further simplification equation processing is being added in the solution calculation process, the difference from the actual voltage of the equipment load may increase.

In particular, the recent power system does not use a passive structure in which respective equipment loads directly receive portions of power transmitted from Korea Electric Power Corporation (KEPCO). Instead, as in electric vehicles or renewable energy power plants, a structure in which equipment loads supply power toward the parent power system or the like is used, thereby increasing the complexity of the power system. Thus, in consideration of the situation of the complicated recent power system, the above-described flow calculation on the bus line will be more complicated. Due to assumptions for the simplified modeling, the difference from the actual optimal operating voltage of the equipment loads may be increased.

FIG. 1 illustrates an embodiment of the voltage control device according to the present disclosure in which branched first to fourth equipment loads 31 to 34 are subjected to the voltage control.

The voltage control device according to the present disclosure may include a data collector 100 comprised of data collecting elements disposed in the equipment loads 31 to 34, respectively, to collect real-time power data.

The respective equipment loads 31 to 34 may be grouped into the single control group 20 to be subjected to the optimal voltage control.

The data collector 100 may be disposed in all of control groups 20 that a manager or a user of the voltage control device manages.

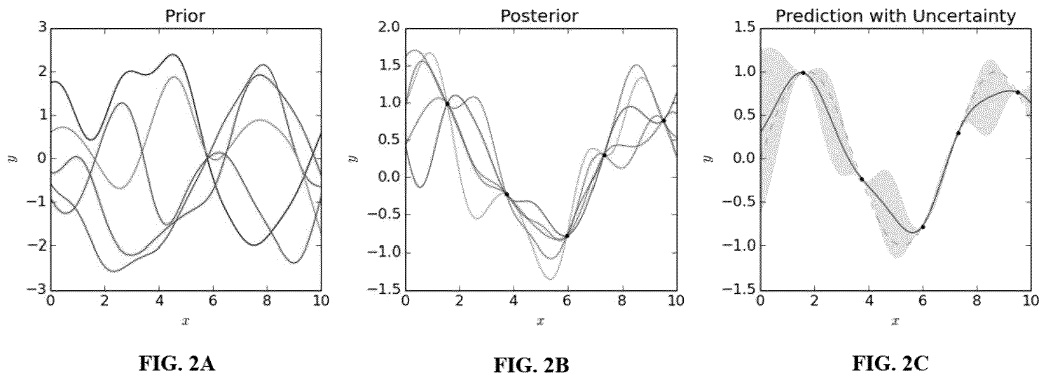

Referring to FIGS. 2A to 5, the voltage prediction and voltage control according to the present disclosure will be described.

The voltage control device according to the present disclosure may include at least one of the data collector 100, a statistics processor 200, a voltage predictor 300, a voltage calculator 400, and a controller 500.

The data collector 100 may collect voltage data from the equipment loads 30 of the control group 20, respectively, by real-time measurement.

The statistics processor 200 may perform prediction processing to voltage data measured by the data collector 100 disposed in all of the equipment loads 30 of the control group according to the prediction period.

The prediction processing performed by the statistics processor 200 may obtain statistical values of the voltage data of the respective equipment loads 30 over time. The statistical values may include a maximum value, a minimum value, a median value, an average value, and the like.

The prediction period may include 1 second, 10 seconds, 1 minute, 15 minutes, and the like.

The voltage control device may calculate the optimal voltage by grouping the entire equipment loads into the single control group 20 instead of calculating the optimal voltage of each of the equipment loads.

When the respective equipment loads have different rated voltages, the voltage control may be performed to each of the equipment loads 30 by performing scaling followed by statistical processing, and after completion of the statistical processing, performing the scaling again.

Instruction to the voltage to be controlled may be performed by a controller 500, and the scaling may also be performed by the controller 500.

In addition, the scaling may be used not only for the voltage but also in synchronization of time units. The equipment loads continuously measured every second may be statistically processed every second, every few seconds, or every tens of seconds. When there is a significant difference between measurement time units, for example, the statistical processing is performed every minute, every half hour, every hour, or the like, depending on the type of the equipment load, the scaling of the time units is also required.

Thus, the scaling by the controller 500 may include voltage scaling and time scaling.

The voltage predictor 300 may calculate a predicted voltage or a predicted voltage distribution by regarding the entirety of the equipment loads of the control group 20 as a single unit, instead of calculating the optimal voltage of each of the equipment load of the control group 20.

This is because when a future voltage distribution is predicted for the respective equipment loads 30, the amount of real-time computation increases and a long time is spent for the future voltage distribution, in which case it is improper to control the plurality of equipment loads 30 in real time.

FIGS. 2A to 2C are graphs sequentially illustrating the prediction process of the future voltage distribution performed by the voltage predictor 300 over time.

In FIGS. 2A to 2C, the horizontal axis may indicate times, and the vertical axis may indicate voltages. The units of the horizontal axis and the vertical axis may be units scaled by the controller 500.

FIG. 2A may illustrate the distribution of voltages measured from the respective equipment loads 30 measured at an initial first time, and FIG. 2B may illustrate the distribution of voltages measured at a second time subsequent to the first time. Here, FIG. 2B is obtained using the voltages measured from the respective equipment loads 30 input at every prediction period between the first time and the second time. FIG. 2C may illustrate a predicted future voltage distribution.

Assumptions for the voltage prediction may decrease from FIG. 2A to FIG. 2C. As the voltage data of the equipment loads is gradually added to the predicted voltage calculation, the assumptions may decrease. Thus, it can be seen that a result converges to a predicted voltage band, i.e., relevant statistical results, and the future voltage prediction is gradually more accurate.

Referring to FIG. 2C, the future distribution calculated by the voltage predictor 300 may be expressed as the average and the distribution of the next prediction period related to statistical values related to the voltage of the entire equipment loads 30.

The predicted voltage distribution calculated by the voltage predictor 300 described with reference to the drawings of this specification is assumed to use the voltage data of the respective equipment loads 30 collected by the data collector 100.

However, the predicted statistical values may be predicted values of a maximum, a minimum, a median, an average, and the like of the voltage.

For example, the voltage predictor 300 may calculate the distribution of the maximum values of ten (10) equipment loads after one minute. Here, the number of the equipment loads 30 belonging to the control group 20 may be 10, and the one minute may be a prediction period.

The future voltage distribution may follow a normal distribution.

The voltage predictor 300 may perform the voltage prediction using statistical values of the statistics processor 200.

The voltage predictor 300 may calculate the future voltage distribution using the average and the distribution of the equipment loads 30.

In an embodiment, the voltage distribution prediction by the voltage predictor 300 may be performed by posterior distribution prediction based on the Bayes algorithm. This is intended to reduce the amount of computation for the prediction of the voltage predictor 300. That is, the voltage data processed by the voltage predictor 300 may not be accumulated.

The amount of data processed by the voltage predictor 300 at every prediction period may not increase. For example, the voltage predictor 300 may perform the voltage prediction using 50 pieces of voltage data at a first prediction period and may also perform the voltage prediction using 50 pieces of voltage data at a second prediction period. That is, the voltage predictor 300 may only be required to process the same number of pieces of voltage data at each prediction period, instead of processing 100 pieces of voltage data at the second prediction period using both the 50 pieces of voltage data input at the first prediction period and the 50 pieces of voltage data input at the second prediction period. The number of pieces of data that the voltage predictor 300 uses in the prediction may be maintained constantly. Thus, the amount of computation does not increase over time, and a time taken for the prediction by the voltage predictor 300 may be reduced.

The voltage predictor 300 may calculate the predicted voltage distribution by machine learning, and hyper-parameters of the machine learning may be configured as follows.

1. The voltage predictor 300 may initialize the average and the distribution. Here, the initialized value may be fixed to a value between 0 and 1 or be given randomly.

2. A first measured value may be added to the memory of the voltage predictor 300. Here, the first measured value may be first voltage data of the equipment loads 30 at the first prediction period.

3. The average and the distribution may be updated using the first voltage data of 2. Forgetting factors may be used in the updating.

4. Second voltage data of the equipment loads 30 at the second prediction period, i.e., the subsequent prediction period, may be input.

5. The voltage predictor 300 may calculate the distance between the first voltage data present in the memory and the newly-input second voltage data. Here, the first voltage data and the second voltage data may be vectors, and a kernel between the first voltage data and the second voltage data may be calculated.

6. A predicted average value and a predicted distribution value may be calculated using the kernel and a normalizing constant.

7. The above-described processes may be repeated.

In this case, when the memory of the voltage predictor 300 is full while the above-described processes are being repeated, some voltage data of the voltage data stored in the memory may be deleted and new voltage data may be added. The deleted voltage data may be a piece of voltage data having a smallest amount of information among the pieces of voltage data stored in the memory.

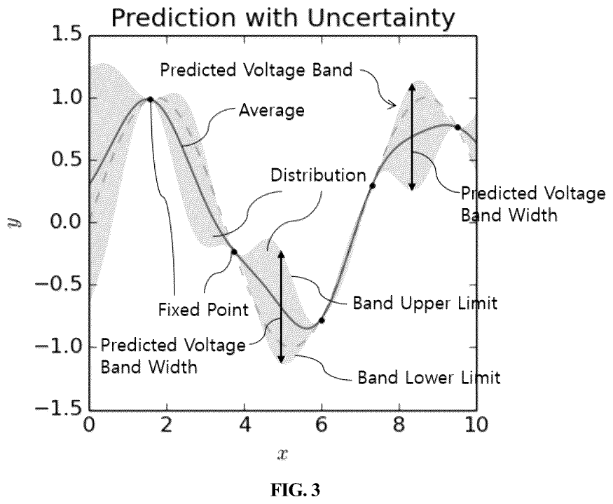

Referring to FIG. 3, the future voltage may be provided in a band type having a band upper limit and a band lower limit from FIG. 2A to FIG. 2C.

The future voltage distribution predicted to be the band type may be referred to as a predicted voltage band. The difference between the band upper limit and the band lower limit at a specific time may be referred to as the width of the predicted voltage band.

The band upper limit may include information regarding maximum voltage values of the plurality of equipment loads 30, and the band lower limit may include information regarding minimum voltage values of the plurality of equipment loads 30.

The predicted voltage band according to the present disclosure is a band type having a width. The band width may be generated due to the distribution.

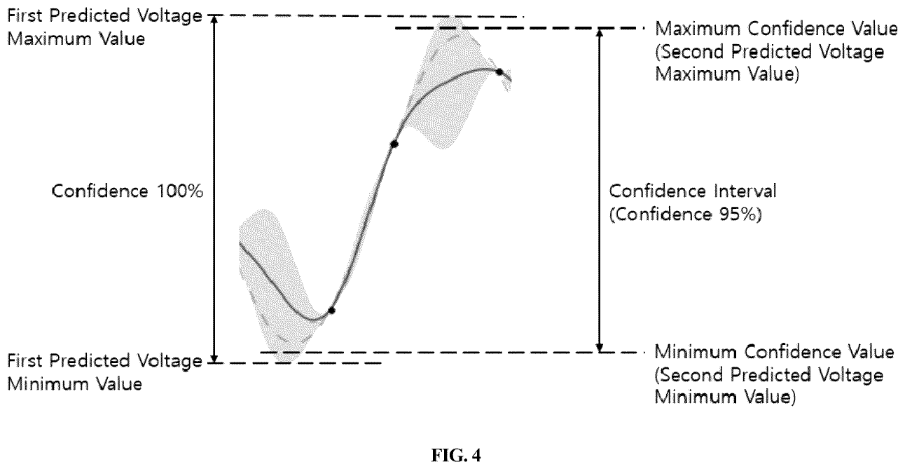

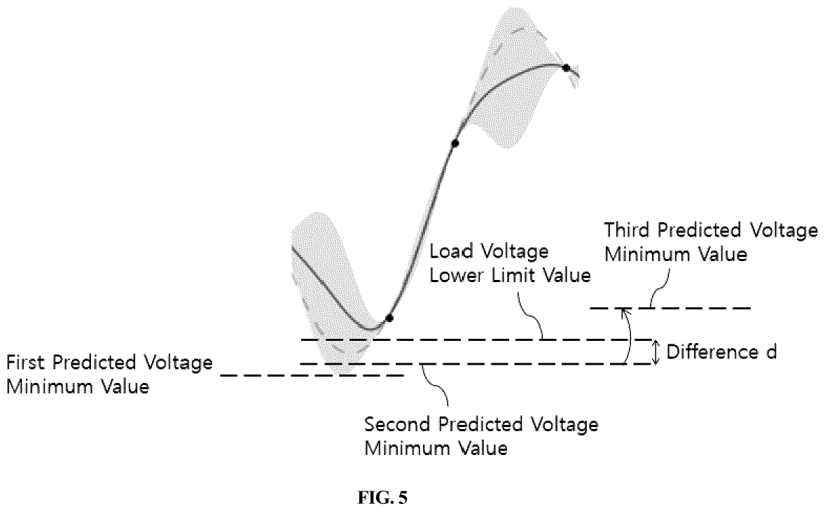

Referring to FIGS. 4 and 5, as a result, the voltage predictor 300 may calculate the future voltage prediction distribution of the band type having the upper limit and the lower limit. This may be referred to as a first predicted voltage. The first predicted voltage may have the maximum value of the first predicted voltage as the upper limit and the minimum value of the first predicted voltage as the lower limit. The maximum value of the first predicted voltage may be the upper limit of the predicted voltage band, and the minimum value of the first predicted voltage may be the lower limit of the predicted voltage band.

The voltage calculator 400 may calculate a control voltage for controlling the voltage of the voltage control device. The controller 500 may generate a voltage control instruction based on the control voltage calculated by the voltage calculator 400.

Here, the voltage calculator 400 may determine the confidence of the predicted future voltage distribution.

Referring to FIG. 4, the voltage calculator 400 may calculate a confidence interval according to the predetermined confidence. The confidence interval may have a maximum confidence value and a minimum confidence value as the upper limit and the lower limit, respectively. The confidence interval may be obtained by correcting the confidence of the first predicted voltage calculated by the voltage calculator 400, the maximum confidence value may be a maximum value of the second predicted voltage, and the minimum confidence value may be a minimum value of the second predicted voltage.

The confidence of the predicted voltage band predicted by the voltage predictor 300 may be regarded as being 100%. FIG. 4 illustrates a case in which the confidence is set to 95%. The confidence and the confidence interval may be changed to any factors related to the accuracy and confidence of the voltage control device by the user.

First, the first predicted voltage (or predicted voltage band) may be calculated on the basis of the actually-measured voltage of the equipment loads 30 by the voltage calculator 400. Afterwards, the second predicted voltage on which the predetermined confidence (e.g., 95%) is reflected may be calculated on the basis of the first predicted voltage.

The confidence interval, i.e., the second predicted voltage, may be included in the predicted voltage band, i.e., the first predicted voltage.

In this case, the prediction by the voltage control device may be interpreted that the predicted voltage distribution of the equipment load group (i.e., the control group 20) at the next prediction period may be included in the confidence interval of the second predicted voltage by a probability of 95%.

The equipment loads 30 are actually-operating machines or devices each of which may have an operable upper limit and an operable lower limit. For example, when the equipment loads 30 operate at 220V, each of the equipment loads 30 may have a limitation, by which the voltage thereof is controlled within the range of 210V to 230V.

The upper limit and the lower limit of each equipment load may be referred to as a load voltage upper limit value and a load voltage lower limit value, respectively.

In most equipment loads 30, the lower limit is frequently a problem. The following description will be based on the lower limit, but the same may apply to the upper limit.

Referring to FIG. 5, the minimum value of the first predicted voltage may be the lower limit of the first predicted voltage, i.e., the predicted voltage band calculated by the voltage predictor 300. The voltage calculator 400 may calculate the confidence interval on the basis of the predetermined confidence, and may calculate the second predicted voltage minimum value, i.e., the minimum confidence value of the lower limit of the confidence interval.

Here, the second predicted voltage minimum value may be compared with the load voltage lower limit value that is the lower limit of the operating limits of the corresponding equipment load 30. When the second predicted voltage minimum value is calculated to be the same or lower than the load voltage lower limit value, the voltage calculator 400 may calculate a third predicted voltage minimum value higher than the load voltage lower limit value. Thus, the third predicted voltage minimum value may be set to be higher than the second predicted voltage minimum value by at least a difference d obtained by subtracting the second predicted voltage minimum value from the load voltage lower limit value. The controller 500 may instruct the voltage control device to operate at the third predicted voltage minimum value.

Summarizing, the voltage calculator 400 may calculate the confidence-based optimal voltage value. That is, the voltage calculator 400 may predict the optimal voltage value on the basis of the user-set confidence of the statistical values of the equipment group calculated on the assumption of a normal distribution.

That is, the equipment loads 30 may have the load voltage lower limit value that is a lower limit condition of unique voltage driving.

The predicted voltage value may be set as the lower limit value (or second predicted voltage minimum value) of the future voltage distribution. A distance (d) from the load voltage lower limit value, i.e., the lower limit condition of the equipment loads 30, may be calculated. The controller 500 may generate a voltage control instruction by reflecting the distance (d). In this case, for cascade control such as tap-type control, the controller 500 may calculate the voltage control value by dividing the distance (d) with a resolution.

Although the exemplary embodiments of the present disclosure have been described for illustrative purposes, those skilled in the art will appreciate that various modifications, additions, and substitutions are possible, without departing from the scope and spirit of the present disclosure as disclosed in the accompanying claims.

What is claimed is:

1. A voltage control device comprising:
a data collector configured for collecting voltage data from a plurality of equipment loads;
a statistics processor configured for statistically processing the voltage data collected by the data collector according to a prediction period;
a voltage predictor configured for predicting a future voltage distribution using statistical values from the statistics processor;
a voltage calculator configured for calculating a voltage to be controlled using the future voltage distribution predicted by the voltage predictor; and
a controller configured for generating an instruction to perform control at the voltage calculated by the voltage calculator.

2. The voltage control device of claim 1, wherein the plurality of equipment loads are branched from a bus line of a power system,
the statistics processor, the voltage predictor, and the voltage calculator are based on the voltage data actually measured by the data collector disposed in each of the plurality of equipment loads instead of being based on a voltage of the bus line.

3. The voltage control device of claim 1, wherein the plurality of equipment loads form a control group subjected to voltage control, and
the voltage is calculated by regarding all of the plurality of equipment loads of the control group as a single unit instead of calculating a voltage to be controlled of each of the plurality of equipment loads.

4. The voltage control device of claim 1, wherein the voltage predictor is configured to calculate a predicted voltage band as a first predicted voltage from the voltage data actually measured from the plurality of equipment loads,
the voltage calculator is configured to set confidence for the predicted voltage band and calculates a confidence interval as a second predicted voltage according to the confidence,
the confidence interval is included in the predicted voltage band, and
when the confidence is X %, a predicted voltage of the plurality of equipment loads at a next prediction period is included in the confidence interval by a probability of X %.

5. The voltage control device of claim 1, wherein the statistics processor is configured to statistically processe the voltage data measured by the data collector according to the prediction period,
the statistical processing of the voltage data obtains a statistical value for the voltage data of each of the plurality of equipment loads over time, and
the statistical value comprises at least one of a maximum value, a minimum value, a median value, and an average value.

6. The voltage control device of claim 1, wherein the statistics processor is configured to statistically processe the voltage data measured by the data collector according to the prediction period,
the statistical processing of the voltage data obtains a statistical value for the voltage data of each of the plurality of equipment loads over time, and
the controller performs voltage scaling and time scaling on the statistical value.

7. The voltage control device of claim 1, wherein the future voltage distribution calculated by the voltage predictor is obtained from an average and a distribution of statistical values related to voltages of the plurality of equipment loads.

8. The voltage control device of claim 1, wherein the statistics processor is configured to statistically processe the voltage data measured by the data collector according to the prediction period, and
voltage data input and processed at a previous prediction period is not accumulated in the voltage data processed by the voltage predictor.

9. The voltage control device of claim 1, wherein the voltage predictor is configured to calculate a predicted voltage band as a band-type future voltage distribution having an upper limit and a lower limit,
the width of the predicted voltage band corresponds to a distribution of the voltage data.

10. The voltage control device of claim 1, wherein the voltage calculator is configured to predict a voltage on the basis of confidence for statistical values of the plurality of equipment loads calculated on assumption of a normal distribution,
a lower limit value of the voltage predicted on the basis of the confidence is set as a lower limit value of the future voltage distribution,
the plurality of equipment loads have a load voltage lower limit value as a lower limit condition of unique voltage driving,
the voltage calculator is configured to calculate a distance from the lower limit value of the future voltage distribution and the load voltage lower limit value, and
the controller is configured to generate a voltage control instruction by reflecting the distance.

11. The voltage control device of claim 10, wherein, for cascade control including tap-type control, the controller is configured to calculate a voltage control value by dividing the distance with a resolution.

12. The voltage control device of claim 1, wherein the voltage predictor is configured to calculate a predicted voltage band as a first predicted voltage from the voltage data actually measured from the plurality of equipment loads,
the voltage calculator is configured to set confidence for the predicted voltage band and calculates a confidence interval as a second predicted voltage according to the confidence,
a lower limit of the predicted voltage band is a first predicted voltage minimum value, and a lower limit of the confidence interval is a second predicted voltage minimum value,
the voltage calculator is configured to compare the second predicted voltage minimum value with a load voltage lower limit value that is a lower limit of operating limits of the plurality of equipment loads, and
when the second predicted voltage minimum value is calculated to be equal to or lower than the load voltage lower limit value, the voltage calculator calculates a third predicted voltage minimum value higher than the load voltage lower limit value.

13. The voltage control device of claim 12, wherein the third predicted voltage minimum value is set to be higher than the second predicted voltage minimum value by at least a difference obtained by subtracting the second predicted voltage minimum value from the load voltage lower limit value, and
the controller instructs an operation to be performed at the third predicted voltage minimum value.

14. The voltage control device of claim 1, wherein the voltage predictor is configured to calculate a predicted voltage distribution by operations of:
(a) initializing, by the voltage predictor, an average and a distribution of the plurality of equipment loads;
(b) inputting first voltage data collected at a first prediction period into memory of the voltage predictor;
(c) updating the average and a distribution using the first voltage data of the operation (b);
(d) inputting second voltage data of the plurality of equipment loads collected at a second prediction period;
(e) calculating a distance between the first voltage data present in the memory of the voltage predictor and the newly-input second voltage data;
(f) calculating a predicted average value and a predicted distribution value of the voltage data using the distance of the operation (e); and
(g) repeating the operations (a) to (f).

15. The voltage control device of claim 14, wherein while the operations (a) to (f) are being repeated, when the memory is full, the voltage predictor deletes some of the voltage data stored in the memory and adds new voltage data, and
the deleted voltage data has a smallest amount of information among the voltage data stored in the memory.
